(19) United States
(12) Patent Application Publication
(10) Pub. No.: US 2017/0194366 A1
(43) Pub. Date: Jul. 6, 2017

(54) METHOD FOR MANUFACTURING THIN-FILM TRANSISTOR

(71) Applicant: CHUNGHWA PICTURE TUBES, LTD., Taoyuan City (TW)

(72) Inventors: Hsi-Ming CHANG, TAOYUAN CITY (TW); Yen-Yu HUANG, Taoyuan City (TW)

(21) Appl. No.: 14/986,739

(22) Filed: Jan. 4, 2016

(51) Int. Cl. H01L 27/12; H01L 29/786

(52) U.S. Cl. CPC H01L 27/1288; H01L 29/7869; H01L 27/1225

(57) ABSTRACT

A method for manufacturing a thin-film transistor is provided, including the following steps. A gate electrode is formed on a substrate. An insulating layer is formed on the gate electrode. A patterned active layer is formed on the insulating layer. A conductive layer having a thickness is formed on the patterned active layer and the insulating layer. The thickness of a first portion of the conductive layer that overlies the patterned active layer is reduced to leave the first portion of the conductive layer over the pattern active layer. The conductive layer is etched to expose the patterned active layer under the first portion of the conductive layer.

### BACKGROUND

Field of Invention

The present invention relates to a method for manufacturing a thin-film transistor. More particularly, the present invention relates to a method for manufacturing a thin-film transistor by multiple-step etching process for conductive layer.

Description of Related Art

A thin-film transistor (TFT) is widely used in computer chip, mobile chip, and liquid crystal display (LCD), etc. Therefore, the manufacturing process of thin-film transistor is required to be developed accordingly. In traditional manufacturing process, an active layer is usually patterned before it is covered by a conductive layer. Next, the conductive layer is usually etched by plasma to form the source and drain of the thin-film transistor in one step. However, after the conductive layer over the patterned active layer is removed, the plasma usually intensively bombards the patterned active layer under the conductive layer rather than bombards the other layers such as photoresist or insulating layer under the conductive layer, such that the patterned active layer is easily damaged and degraded.

In other traditional manufacturing process, a conducting layer is formed on an active layer which is not patterned. Subsequently, the conducting layer is etched. Then, the active layer is patterned. However, the patterned active layer is usually asymmetric because of inaccurate alignment during exposure. The asymmetric patterned active layer would complicate the subsequent manufacturing process and design.

In view of the existing problems above, an improved method for manufacturing a thin-film transistor is required.

### SUMMARY

The present invention provides a new method for manufacturing a thin-film transistor (TFT), which can protect a patterned active layer of the TFT from damage caused by plasma thereby obtain the TFT with good quality.

An aspect of the present invention provides a method for manufacturing a thin-film transistor, including the following steps. A gate electrode is formed on a substrate. An insulating layer is formed on the gate electrode. A patterned active layer is formed on the insulating layer. A conductive layer having a thickness is formed on the patterned active layer and the insulating layer. The thickness of a first portion of the conductive layer that overlies the patterned active layer is reduced to leave the first portion of the conductive layer over the pattern active layer. The conductive layer is etched to expose the patterned active layer under the first portion of the conductive layer.

According to one embodiment of the present invention, the step of etching the conductive layer is by plasma etching with SF₆+O₂ plasma or CH₄+O₂ plasma.

According to one embodiment of the present invention, the step of etching the conductive layer comprises reducing the thickness of a second portion of the conductive layer, wherein the second portion of the conductive layer overlies the insulating layer.

According to one embodiment of the present invention, the method further includes a step of removing the second portion of the conductive layer.

According to one embodiment of the present invention, the method further includes a step of forming a patterned protective photoresist layer over the patterned active layer, before the step of removing the second portion of the conductive layer.

According to one embodiment of the present invention, the method further includes a step of removing the patterned protective photoresist layer, after the step of removing the second portion of the conductive layer.

According to one embodiment of the present invention, the step of reducing the thickness of the first portion of the conductive layer includes the following steps. A patterned photoresist layer is formed over the conductive layer to expose the first portion of the conductive layer, wherein the substrate has a first region surrounding the first portion of the conductive layer and a second region, wherein the patterned photoresist layer over the first region having a first thickness thicker than a second thickness of the patterned photoresist layer over the second region. The first portion of the conductive layer is etched.

According to one embodiment of the present invention, wherein the step of forming the patterned photoresist layer includes the following steps. A photoresist layer is formed over the conductive layer. The photoresist layer is patterned by a gray scale mask.

According to one embodiment of the present invention, the method further includes a step of removing the patterned photoresist layer having the second thickness to expose a second portion of the conductive layer, wherein the second portion of the conductive layer overlies the insulating layer, after the step of etching the first portion of the conductive layer.

According to one embodiment of the present invention, the method further includes a step of forming a patterned protective layer on the conductive layer and forming a pixel electrode connecting with the conductive layer, after the step of etching the conductive layer.

Advantage of the present invention is that by patterning the conductive layer over the patterned active layer in two steps including, firstly, the thickness of the conductive layer over the patterned active layer is reduced to leave the conductive layer over the pattern active layer and, secondly, the conductive layer over the pattern active layer is etched to expose the patterned active layer to form source and drain of TFT without damaging the patterned active layer, and thus keep the performance of the patterned active layer.

### BRIEF DESCRIPTION OF THE DRAWINGS

FIGS. 1 through 15 are schematic cross-sectional views of a thin-film transistor at various manufacturing stages according to an embodiment of the present invention.

### DETAILED DESCRIPTION

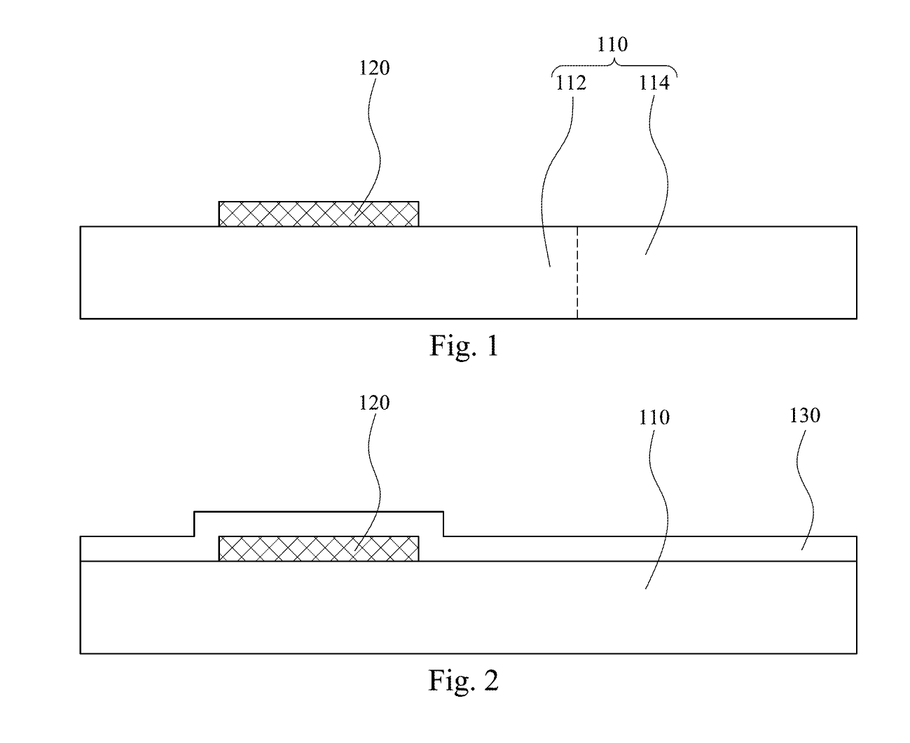

Referring to FIG. 1, FIG. 1 shows that a gate electrode 120 is formed on a substrate 110. The substrate 110 has a first region 112 and a second region 114. The first region 112 is for receiving gate electrode, insulating layer covering gate electrode, patterned active layer, source and drain in subsequent manufacturing processes. In addition to the first region 112 of the substrate 110, the remaining portion of the substrate 110 is the second region 114. In one embodiment, the substrate 110 is a glass substrate. In one embodiment, the gate electrode 120 is a metal layer or stacked metal layers. A material of the gate electrode 120 includes molybdenum (Mo), aluminum (Al), titanium (Ti), tantalum (Ta), copper (Cu), tin (Sn), nickel (Ni), gold (Au), silver (Ag), tungsten (W), chromium (Cr), platinum (Pt), metal alloy, other electrically conductive material or a combination thereof. In one embodiment, the gate electrode 120 is formed by the following steps. A gate layer (not shown) is deposited on the substrate 110 by sputtering and the gate layer is subsequently patterned to form the gate electrode 120.

Referring to FIG. 2, FIG. 2 shows that an insulating layer 130 is formed on the gate electrode 120 and the substrate 110. A material of the insulating layer 130 may be silicon monoxide (SiO), silicon dioxide (SiO₂), aluminum oxide (Al₂O₃), silicon nitride (SiₓN_{y}), tantalum pentoxide (Ta₂O₅), Zircon (ZrO₂) or a combination thereof. The insulating layer 130 may be formed by any suitable deposition process. Examples of the deposition process include but are not limited to atomic layer deposition (ALD), chemical vapor deposition (CVD), low pressure chemical vapor deposition (LPCVD), physical vapor deposition (PVD), sputtering and spin-on.

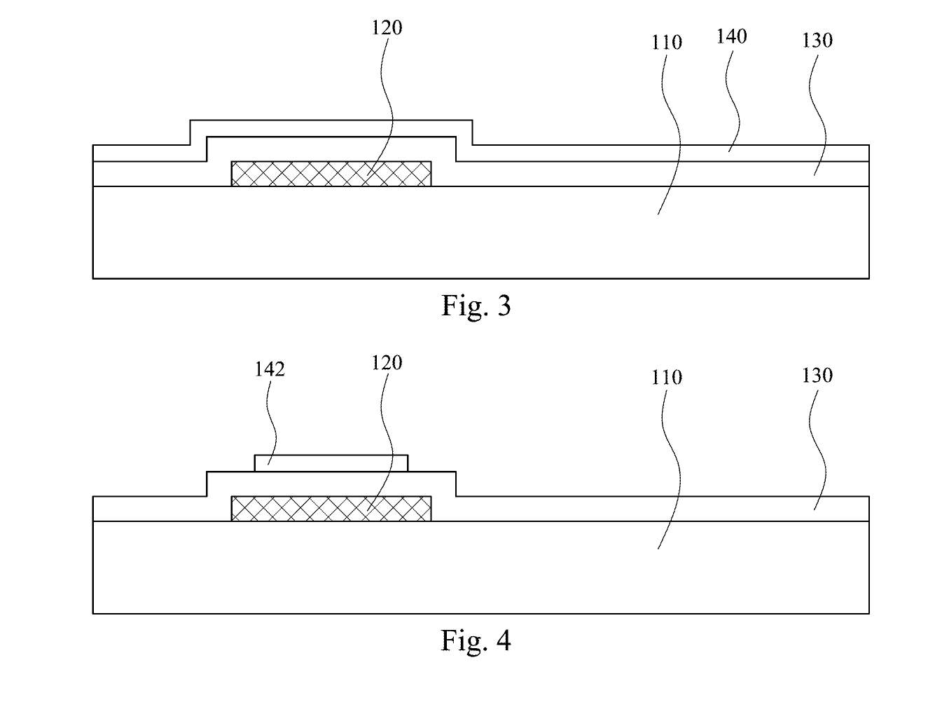

Referring to FIG. 3, FIG. 3 shows that an active layer 140 is formed on the insulating layer 130. A material of the active layer 140 may be any suitable semiconductor material such as metal oxide. For example, metal oxide includes but not limited to indium gallium zinc oxide (IGZO), indium zinc oxide (InZnO), indium tin oxide (ITO), hafnium indium zinc oxide (HfInZnO), zinc oxide (ZnO), zinc oxynitride (ZnON), copper oxide (CuO), indium oxide (In₂O₃) or tin oxide (SnO). The active layer 140 may be formed by ALD, CVD, LPCVD, PVD, sputtering and spin-on.

Referring to FIG. 4, the active layer 140 is patterned to form a patterned active layer 142 over the gate electrode 130 as shown in FIG. 4. The patterning processes are known by the person having ordinary skill in the art, such as coating photoresist, exposing, developing, etching and stripping.

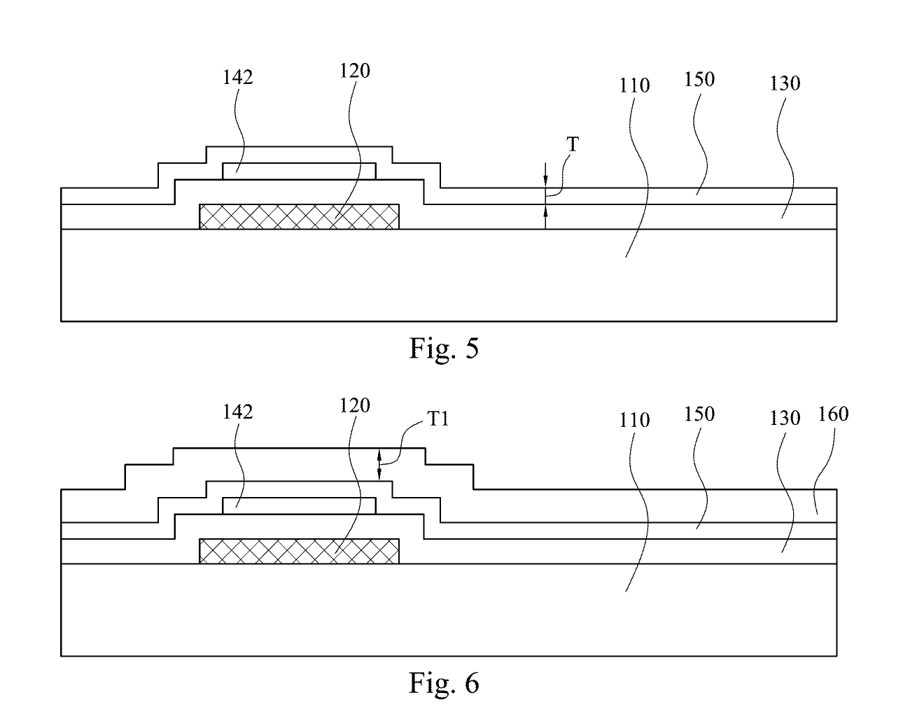

Referring to FIG. 5, FIG. 5 shows a conductive layer 150 having a thickness T is formed on the patterned active layer 142 and the insulating layer 130. In one embodiment, the conductive layer 150 is a metal layer or stacked metal layers. A material of the conductive layer 150 includes molybdenum (Mo), aluminum (Al), titanium (Ti), tantalum (Ta), copper (Cu), tin (Sn), nickel (Ni), gold (Au), silver (Ag), tungsten (W), chromium (Cr), platinum (Pt), metal alloy, other electrically conductive material or a combination thereof.

Referring to FIG. 6, FIG. 6 shows a photoresist layer 160 is formed over the conductive layer 150. The photoresist layer 160 has a thickness of T1.

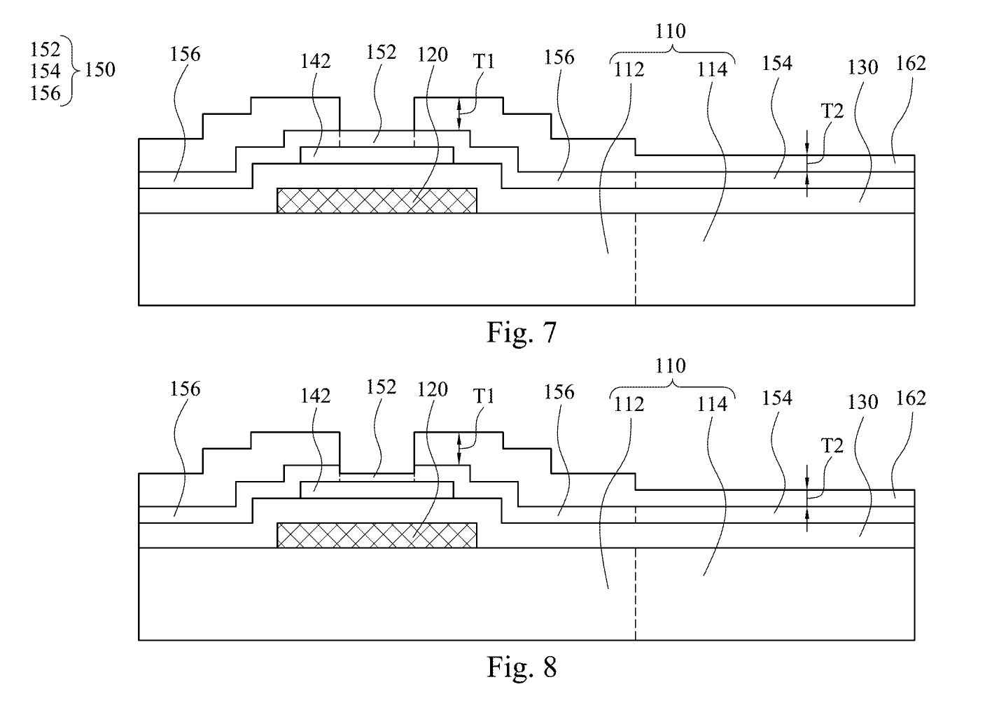

Referring to FIG. 7, FIG. 7 shows that the photoresist layer 160 is patterned to form a patterned photoresist layer 162 to expose the conductive layer 150. For clarity, the conductive layer 150 under the patterned photoresist layer 162 is divided into a first portion 152, a second portion 154 and a third portion 156. More specifically, the first portion 152 of the conductive layer 150 overlies the patterned active layer 142. The second portion 154 of the conductive layer 150 overlies the insulating layer 130. The third portion 156 of the conductive layer 150 conformally overlies the patterned active layer 142 and the insulating layer 130. Accordingly, in other words, the patterned photoresist layer 162 is formed over the conductive layer 150 to expose the first portion 152 of the conductive layer 150 as shown in FIG. 7.

As mentioned above, the substrate 110 has the first region 112 and the second region 114. As shown in FIG. 7, the first portion 152 of the conductive layer 150 is over the substrate 110 and surrounded by the first region 112 of the substrate 110. The patterned photoresist layer 162 over the first region 112 has a first thickness T1 and the patterned photoresist layer 162 over the second region 114 has a second thickness T2. The first thickness T1 is thicker than the second thickness T2.

The photoresist layer 160 may be patterned by any suitable mask. In one embodiment, the photoresist layer 160 is patterned by a gray scale mask. For example, the gray scale mask is a half-tone mask or a gray-tone mask.

Referring to FIG. 8, the thickness of the first portion 152 of the conductive layer 150 as shown in FIG. 7 is reduced to leave the first portion 152 of the conductive layer 150 over the pattern active layer 142 as shown in FIG. 8. In other words, the first portion 152 of the conductive layer 150 as shown in FIG. 8 is thinner than the first portion 152 of the conductive layer 150 as shown in FIG. 7. More specifically, a portion of the first portion 152 of the conductive layer 150 is removed without exposing the patterned active layer 142.

In one embodiment, the thickness of the first portion 152 of the conductive layer 150 is reduced by an etching process. The etching process is a dry etching, a wet etching, and/or other etching methods. For example, the dry etching includes reactive ion etching (RIE) or plasma etching with an etching gas such as an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or a combination thereof. In one embodiment, the plasma etching is performed with SF₆+O₂ plasma or CH₄+O₂ plasma. For example, the wet etching process may use an etchant such as mixture of aqueous phosphoric acid, acetic acid and nitric acid (PAN), diluted hydrofluoric acid (DHF), potassium hydroxide (KOH) solution, ammonia, or other suitable wet etchant.

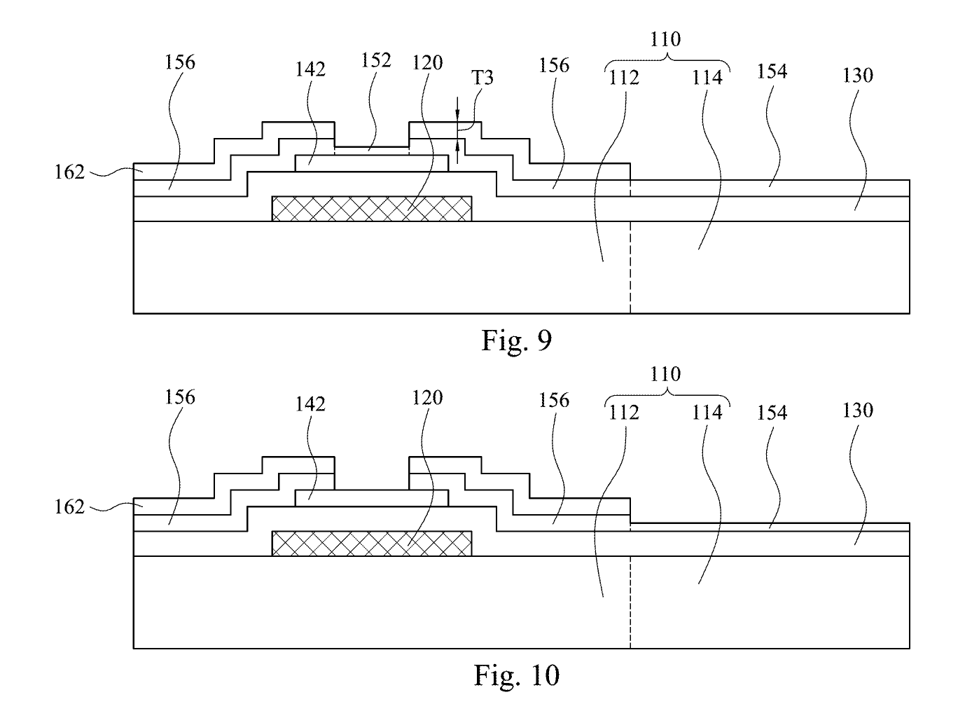

Referring to FIG. 9, FIG. 9 shows that the first thickness T1 and the second thickness T2 of the patterned photoresist layer 162 are reduced. More specifically, the first thickness T1 of the patterned photoresist layer 162 is reduced to a third thickness T3. Moreover, the patterned photoresist layer 162 having the second thickness T2 is removed to expose the second portion 154 of the conductive layer 150. In one embodiment, the first thickness T1 and the second thickness T2 of the patterned photoresist layer 162 are reduced by ashing. Because the first thickness T1 is thicker than the second thickness T2, only the patterned photoresist layer 162 having the second thickness T2 is entirely removed after ashing.

Referring to FIG. 10, FIG. 10 shows that the conductive layer 150 is etched to expose the patterned active layer 142 under the first portion 152 of the conductive layer 150 and to reduce the thickness of the second portion 154 of the conductive layer 150. In other words, the first portion 152 of the conductive layer 150 is removed. The conductive layer 150 may be etched by a dry etching and/or other etching methods. The step of the etching process refer to the above description of etching the first portion 152 of the conductive layer 150.

In one embodiment, the conductive layer 150 is etched by plasma etching. For example, the plasma may be generated from an etching gas such as an oxygen-containing gas, a fluorine-containing gas, a chlorine-containing gas, a bromine-containing gas, an iodine-containing gas, other suitable gases and/or a combination thereof. More specifically, the conductive layer 150 is etched by the plasma etching with SF₆+O₂ plasma or CH₄+O₂ plasma. It is worth noting that both the first portion 152 and the second portion 154 of the conductive layer 150 are exposed to plasma simultaneously. When the first portion 152 of conductive layer 150 is removed, the second portion 154 of the conductive layer 150 still remains on the insulating layer 130. Therefore, the plasma bombards the second portion 154 of the conductive layer 150 rather than intensively bombards the patterned active layer 142 such that the patterned active layer 142 under the first portion 152 keeps its original property and structure as much as possible, after the first portion 152 of the conductive layer 150 is removed.

In a preferred embodiment, the first portion 152 and the second portion 154 of the conductive layer 150 are etched by CH₄+O₂ plasma. Compared to other plasma, an etching ability of the CH₄+O₂ plasma is weaker. Therefore, the patterned active layer 142 is not easily damaged during etching process.

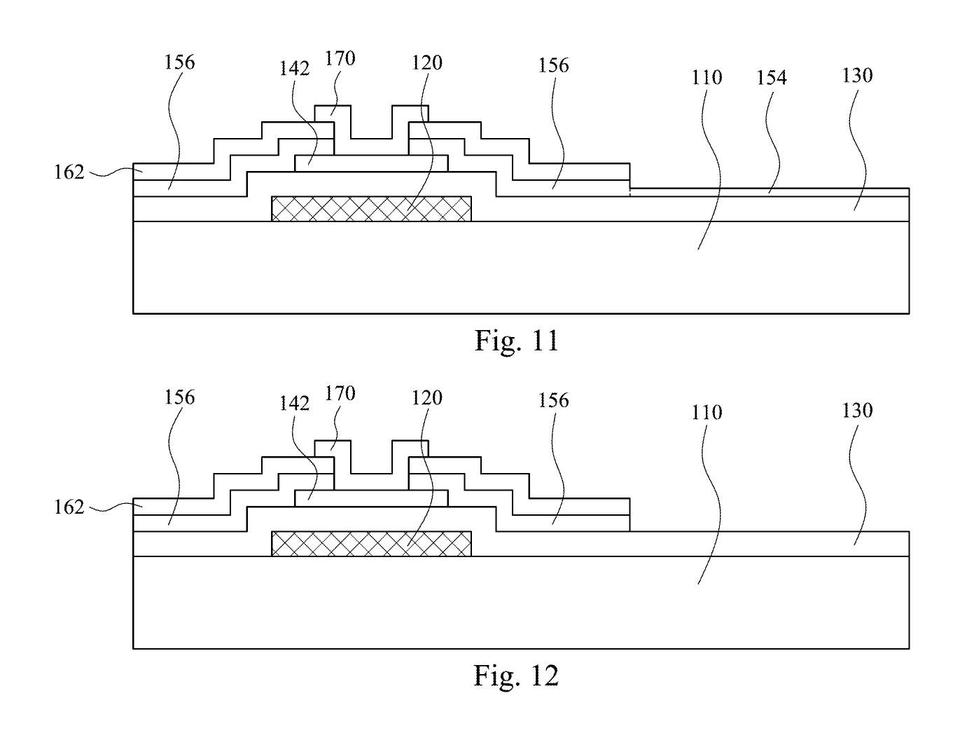

Referring to FIG. 11, FIG. 11 shows that a patterned protective photoresist layer 170 is formed over the patterned active layer 142. In one embodiment, a photoresist layer is formed over the patterned active layer 142, the patterned photoresist layer 162 and the second portion 154 of the conductive layer 150. Subsequently, a patterned mask is formed over the photoresist layer. Next, the pattern of the mask is transferred to the photoresist layer after exposure and development to form the patterned protective photoresist layer 170. The patterned protective photoresist layer 170 is made of any suitable material such as poly (p-hydroxystyrene) or polyacrylate.

Referring to FIG. 12, FIG. 12 shows that the second portion 154 of the conductive layer 150 is removed such that only the third portion 156 of the conductive layer 150 remains. The third portion 156 of the conductive layer 150 is source and drain of the thin-film transistor 100. The second portion 154 of the conductive layer may be removed by a dry etching, a wet etching, and/or other etching methods.

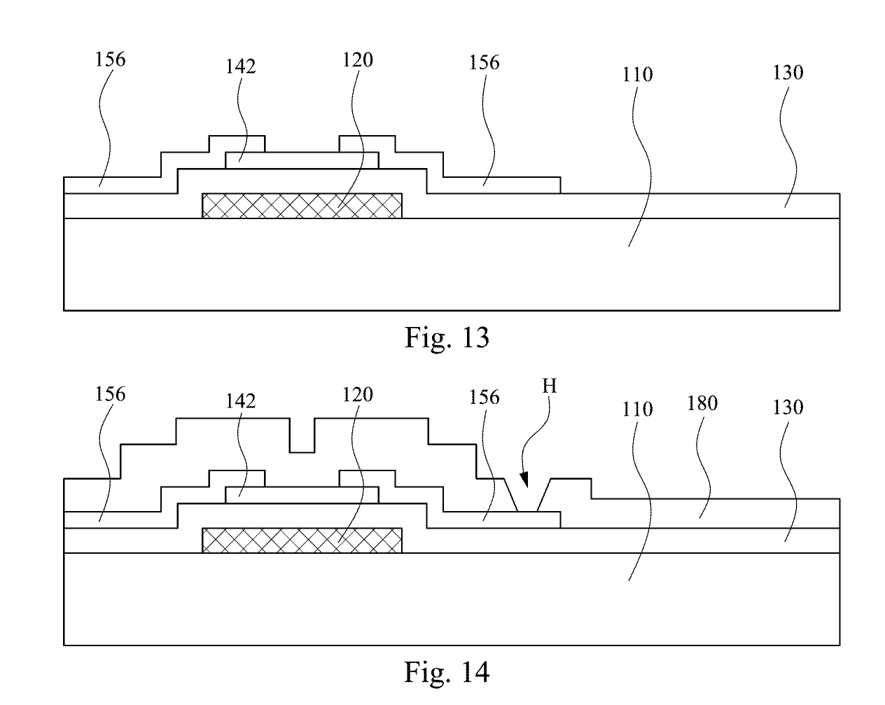

Referring to FIG. 13, FIG. 13 shows that the patterned protective photoresist layer 170 and the patterned photoresist layer 162 are removed such that the third portion 156 of the conductive layer 150 is exposed. Accordingly, from the FIGS. 5 through 13, the conductive layer 150 shown in FIG. 5 is patterned to form the third portion 156 of the conductive layer 150 shown in FIG. 13 by multiple-step etching process. In other words, the present disclosure provides a method for patterning the conductive layer over the patterned active layer without damaging the patterned active layer.

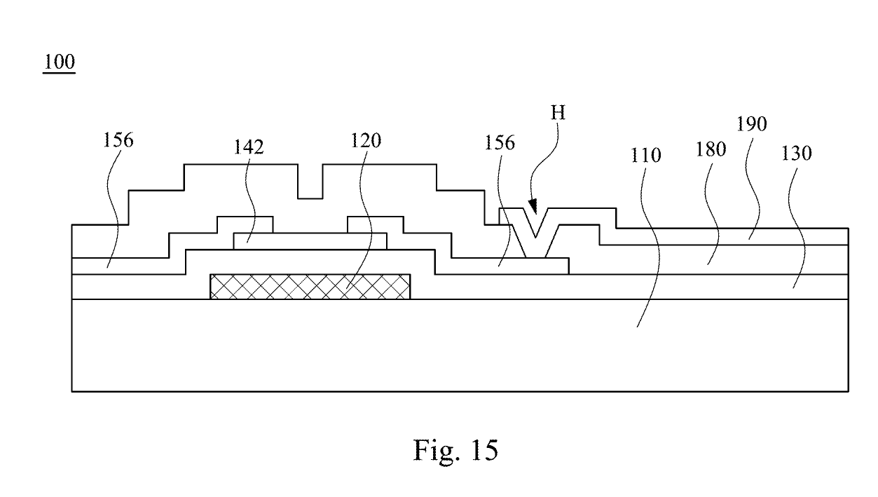

Referring to FIG. 14, FIG. 14 shows that a patterned protective layer 180 with a through hole H is formed on the third portion 156 of the conductive layer 150, the patterned active layer 142 and the insulating layer 130 to prevent the formation of the film which causes the increase in contact resistance over the conductive layer 150. A material of the patterned protective layer 180 includes silicon oxide (SiO), silicon oxide (SiO₂), silicon nitride (Si₃N₄), silicon oxynitride (SiOₓN_{y}), aluminum oxide (Al₂O₃), aluminum nitride (AlN), aluminum oxynitride (AlON) or a combination thereof.

Referring to FIG. 15, FIG. 15 shows that a pixel electrode 190 is formed on the patterned protective layer 180 and connects with the third portion 156 of the conductive layer 150 via the through hole H to form the thin-film transistor 100. A material of the pixel electrode 190 is similar to the material of the conductive layer 150.

The present disclosure provides a method for manufacturing a thin-film transistor (TFT). A portion of a conductive layer of the TFT that overlies a patterned active layer is etched in two steps. In the second step, in addition to the portion of the conductive layer overlying the patterned active layer, a portion of the conductive layer overlying an insulating layer thicker than the portion of the conductive layer overlying the patterned active layer is exposed to the plasma at the same time. Therefore, after the portion of the conductive layer overlying the patterned active layer is removed, the plasma bombards the conductive layer overlying an insulating layer rather than intensively bombards the patterned active layer. Accordingly, the patterned active layer keeps its original property and structure as much as possible and thus the TFT with good quality is obtained.

Although the present invention has been described in considerable detail with reference to certain embodiments thereof, other embodiments are possible. Therefore, the spirit and scope of the appended claims should not be limited to the description of the embodiments contained herein.

1. A method for manufacturing a thin-film transistor, comprising the following steps:
forming a gate electrode on a substrate;
forming an insulating layer on the gate electrode;
forming a patterned active layer on the insulating layer;
forming a conductive layer having a thickness on the patterned active layer and the insulating layer, wherein the conductive layer is in direct contact with an upper surface of the patterned active layer;
reducing the thickness of a first portion of the conductive layer that overlies the patterned active layer to leave the first portion of the conductive layer over the pattern active layer; and
etching the conductive layer to expose the patterned active layer under the first portion of the conductive layer.

2. The method of claim 1, wherein the step of etching the conductive layer is by plasma etching with SF₆+O₂ plasma or CH₄+O₂ plasma.

3. The method of claim 1, wherein the step of etching the conductive layer comprises reducing the thickness of a second portion of the conductive layer, wherein the second portion of the conductive layer overlies the insulating layer.

4. The method of claim 3, further comprising a step of removing the second portion of the conductive layer.

5. The method of claim 4, further comprising a step of forming a patterned protective photoresist layer over the patterned active layer, before the step of removing the second portion of the conductive layer.

6. The method of claim 5, further comprising a step of removing the patterned protective photoresist layer, after the step of removing the second portion of the conductive layer.

7. The method of claim 1, wherein the step of reducing the thickness of the first portion of the conductive layer comprises:
forming a patterned photoresist layer over the conductive layer to expose the first portion of the conductive layer, wherein the substrate has a first region surrounding the first portion of the conductive layer and a second region, wherein the patterned photoresist layer over the first region having a first thickness thicker than a second thickness of the patterned photoresist layer over the second region; and
etching the first portion of the conductive layer.

8. The method of claim 7, wherein the step of forming the patterned photoresist layer comprises:
forming a photoresist layer over the conductive layer; and
patterning the photoresist layer by a gray scale mask.

9. The method of claim 7, further comprising a step of removing the patterned photoresist layer having the second thickness to expose a second portion of the conductive layer, wherein the second portion of the conductive layer overlies the insulating layer, after the step of etching the first portion of the conductive layer.

10. The method of claim 1, further comprising a step of forming a patterned protective layer on the conductive layer and forming a pixel electrode connecting with the conductive layer, after the step of etching the conductive layer.
